(19) United States
(12) Patent Application Publication
(10) Pub. No.: US 2010/0218825 A1
(43) Pub. Date: Sep. 2, 2010

(54) Dye for dye-sensitized solar cell and Solar cell using it

(75) Inventors: Jong-Gi Jee, Daegu-Si (KR); Hye-Kyung Song, Daegu-Si (KR); Ju-Tak Han, Daegu-Si (KR)

Correspondence Address: Revolution IP, PLLC, 5234 Capon Hill Place, Burke, VA, 22015, US

(73) Assignees: KYUNGPOOK NATIONAL UNIVERSITY INDUSTRY ACADEMIC COOPERATION FOUNDATION, Daegu (KR); TAEGU TECHNOPARK, Daegu (KR)

(21) Appl. No.: 12/594,839

(22) PCT Filed: Apr. 1, 2008
(86) PCT No.: PCT/KR2008/001822

§ 371 Date: Oct. 6, 2009

(30) Foreign Application Priority Data
Apr. 6, 2007 (KR) 10-2007-0034375

(51) Int. Cl. H01L 31/00

(52) U.S. Cl. 136/261; 136/252

(57) ABSTRACT

The present invention relates to a new dye for dye-sensitized solar cell and a solar cell prepared using the said dye, more specifically, to a new compound of dye is esterificated to add carboxylate group to alkyl chain, thereby improving a stability on electrolyte and semiconductor particles

### TECHNICAL FIELD

The present invention relates to a dye for dye-sensitized solar cell and a solar cell manufactured using the said dye, more specifically, to a new compound of dye improving stability on electrolyte and semiconductor particles.

### BACKGROUND ART

Recently, in order to solve an energy problem, various studies are on for fuels alternative to fossil fuel. Especially, to alternate to oil which would be exhausted within several decades, wide studies are dealing with a use of nature energy like wind power, nuclear power, solar power etc. Among them, solar cell using solar energy can use unlimited and environment-friendly resource, which is different from other energy source, thus a silicon solar cell is in the limelight ever since the Si-solar cell was developed in 1983.

However, the above silicon solar cell costs very high, thus it is difficult to put to practical use. Moreover, it has a trouble improving an efficiency of solar cell. To overcome these problems, it is necessary to developing a dye-sensitized solar cell which the production cost is very low

A dye-sensitized solar cell is a photoelectric and chemical solar cell comprising photosensitive dye molecules capable of absorbing a visible light and thereby producing electron-hole pairs; and transition metal oxides capable of transporting the produced electrons, as main components, which is different from silicon solar cell. The dye-sensitized solar cell has a low cost and a high converting efficiency compared to the preexisted p-n types of silicon solar cell, thus it can be alternatable cell to preexisted amorphous silicon solar cell.

The team of Michael Gratzel in Ecole Polytechnique Federale de Lausanne (EPFL) has studied about the dye-sensitized solar cell since the dye-sensitized nanoparticle TiO2 (Anatase structure) solar cell was developed in 1991. As a dye for dye-sensitized solar cell, N3 (4,4′-dicarboxylic acid-2,2′-bipyridine)-ruthenium(II) synthesized by the team of Michael Gratze has been used widely in the art. This dye-sensitized solar cell costs low and can be applied to glass windows in outer wall of buildings or glass house, and the like. Continuously, new amphiphile N3-based materials have been synthesized.

As following a pace with this technical stream, a dye having a high stability in electrolyte and semiconductor particles (TiO2 etc.) of solar cell is required as a dye for dye-sensitized solar cell.

### SUMMARY OF THE INVENTION

Accordingly, corresponding to the said requirement, the present inventors have persevered in their efforts in order to develop an amphiphile N3-based dye having a high stability in electrolyte and semiconductor oxide, thereby completing the present invention.

A main object of the present invention is to provide a dye for dye-sensitized solar cell showing a high stability.

Another object of the present invention is to provide a dye-sensitized solar cell comprising the said dye.

In order to achieve the above object, as one aspect, the present invention provides a dye for dye-sensitized solar cell comprising a metal complex having the structures represented by the following chemical formula 1:

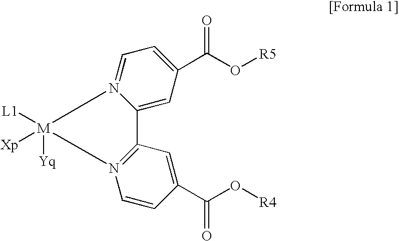

wherein,
M is a transition metal;
L1 is a ligand of the following formula (a)

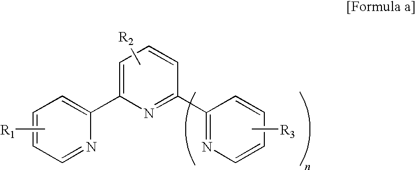

(herein, R₁, R₂, and R₃ are independently selected from —CO₂H, —PO₃H, —SO₃H, —CO₂⁻, —PO₃⁻, —SO₃⁻, alkyl, alkoxy, aryl, heteroaryl, acyl, arylene, alkylene, aryloxy, or alkyleneoxy; n is an integer of zero or one);
R₄ and R₅ are independently selected from alkyl, cycloalkyl, alkoxyalkyl, acylalkyl, haloalkyl or arylalkyl;
X and Y are independently selected from the group consisting of H, NO₂, Cl, Br, I, CN, CNS, H₂O, NH₃, Cr, Br⁻, I⁻, CN⁻, CNS⁻ and PF₆;
p and q are independently an integer of zero to four.

The present invention still provides a dye for dye-sensitized solar cell comprising:

a first electrode comprising a transparent substrate, a light absorbing layer formed on any one side of the first electrode, a second electrode arranged to confront (face) the first electrode, and an electrolyte filled between the first electrode and the second electrode; wherein the light absorbing layer comprises the said dye and semiconductor particles.

When used with the new compound as dye for dye-sensitized solar cell, the cell has a high stability in electrolyte as well as semiconductor particles comprising of TiO₂ etc., thereby getting various advantages, for example, lengthening the cell's life.

### BRIEF DESCRIPTION OF DRAWINGS

FIG. 1 is a rough diagram of the dye-sensitized solar cell according to one embodiment of the present invention.

### AN EXPLANATION OF MARKS IN DRAWINGS

10: sunlight
11: first electrode
12: light absorbing layer
13: electrolyte layer
14: second electrode

### DETAILED DESCRIPTION OF THE INVENTION, AND PREFERRED EMBODIMENTS

To be continued, the preferable examples of the present invention are explained in detail as referring to attached Figures.

In dye-sensitized solar cell, the first step in working a solar cell is a process of producing photocharges from photoenergy. To produce photocharges, dye molecules are used, and the dye molecules absorb the light transmitted through a conductive transparent substrate, thereby being excited. Such dye materials used widely are metal complexes, as like complex salt of mono, bis, or tris (substituted 2,2-bipyridine) of ruthenium.

One of important factors in dye designation is a thermal stability. Especially, dyes for solar cell should be stable both in electrolyte and semiconductor particles.

Accordingly, the present invention provides a dye having a high stability, which comprises new compounds comprising a metal complex having the structures represented by the following chemical formula 1:

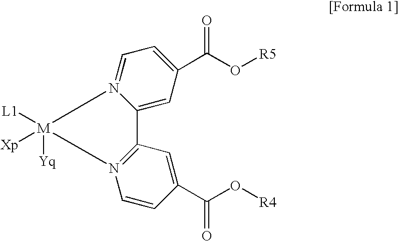

wherein,
M is a transition metal;
L1 is a ligand of the following formula (a)

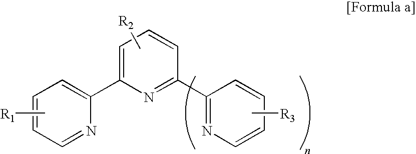

(herein, R₁, R₂, and R₃ are independently selected from —CO₂H, —PO₃H, —SO₃H, —CO₂⁻, —PO₃⁻, —SO₃⁻, alkyl, alkoxy, aryl, heteroaryl, acyl, arylene, alkylene, aryloxy, or alkyleneoxy; n is an integer of zero or one);
R₄ and R₅ are independently selected from alkyl, cycloalkyl, alkoxyalkyl, acylalkyl, haloalkyl or arylalkyl;
X and Y are independently selected from the group consisting of H, NO₂, Cl, Br, I, CN, CNS, H₂O, NH₃, Cl⁻, Br⁻, I⁻, CN⁻, CNS⁻ and PF₆;
p and q are independently an integer of zero to four.

In the metal complex of the Formula 1, the M is preferably selected from the group consisting of Ru, Os, Ir, Co, Rh, Zr, Zn and Pd, more preferably, M is Ru.

In the present invention, ‘alkyl’ as used herein refers to straight-, branched-, or cyclic hydrocarbon structure and the combination thereof, which includes low alkyl and high alkyl, preferably from 1 to 12 carbons. Low alkyl refers to the alkyl group having from 1 to 6 carbons, preferably, from 1 to 4. Exemplary alkyl groups include methyl, ethyl, n-propyl, isopropyl, and n-, s- and t-butyl, and the like. High alkyl refers to the alkyl group having not less than 7 carbons, preferably, form 7 to 20 carbons, which include n-, s- and t-heptyl, octyl and dodecyl. Cycloalkyl is a subset of alkyl group; it includes cyclic hydrocarbons of 3 to 8 carbons. Exemplary cycloalkyl group comprises cyclopropyl, cyclobutyl, cyclopentyl and norbornyl.

In one aspect of the present invention, the alkyl is preferably selected from the group consisting of straight- and branched alkyls of 1 to 20 carbons, more preferably, straight- and branched alkyls of 1 to 12 carbons, and still more preferably from the low alkyl of 1 to 6 carbons comprising methyl, ethyl, n-propyl, isopropyl, and n-butyl, sec-butyl, t-butyl, pentyl, iso-amyl, hexyl, most preferably, low alkyl radical of 1 to 3 carbons.

The term ‘aryl’ and ‘heteroaryl’ refer to 5- or 6-members of aromatic or heteroaromatic ring containing 0 to 3 of heteroatoms selected from nitrogen, oxygen and sulfur; bicyclic 9- or 10-members of aromatic or heteroaromatic ring containing 0 to 3 of heteroatoms selected from nitrogen, oxygen and sulfur; tricyclic 13- or 14-members of aromatic or heteroaromatic ring containing 0 to 3 of heteroatoms selected from nitrogen, oxygen and sulfur. The said aromatic 6- to 14-members of carbocyclic rings includes benzene, naphthalene, indane, tetralin and fluorine. The said 5 to 10-members aromatic heterocyclic rings are for example, imidazole, pyridine, indole thiophene, benzopyranone, thiazole, furan, benzimidazole, quinoline, isoquinoline, quinoxaline, pyrimidine, pyrazin, tetrazole and pyrazole.

The aryl can be used as solely or in a combination, preferred aryl groups are 6 to 30 carbons of carbocyclic aromatic compounds comprising one or more rings such as phenyl, naphtyl, tetrahydronaphtyl, indane, and biphenyl. Herein, the rings can be held together by a pendant method or fused together. More preferably, the aryl is phenyl. Furthermore, the aryl can have 1 to 3 of substituent such as hydroxy, halo, haloalkyl, nitro, cyano, alkoxy, or low alkylamino of from 1 to 6 carbons.

The term ‘acyl’ refers to the group having 1 to 8 carbons of straight-, branched-, or cyclic forms of saturated, unsaturated and aromatic group and the combination thereof, which is bound with a parent structure by carbonyl functional group. One or more carbons of acyl residues can be substituted for nitrogen, oxygen, or sulfur, if when the binding site to the parent structure is located at the carbonyl. For example, there is acetyl, benzoyl, propyonyl, isobutyryl, t-butoxycarbonyl, and benzyloxycarbonyl. Low acyl refers to the group having 1 to 4 carbons.

The term ‘alkoxy’ refers to the group having 1 to 8 carbons of straight-, branched-, or cyclic forms and the combination thereof, which is bound with a parent structure by oxygen. For example, there is methoxy, ethoxy, propoxy, isopropoxy, cyclopropyloxy and cyclohexyloxy.

Low alkoxyl refers to the group having 1 to 4 carbons. Preferably, the alkoxy is selected from the group consisting of oxygen-contained straight-, branched-alkoxy having 1 to 20 carbons, more preferably, low alkoxy having 1 to 6 carbons such as methoxy, ethoxy, propoxy, butoxy and t-butoxy, still more preferably, low alkoxy having 1 to 3 carbons.

Moreover, the alkoxy comprises haloalkoxy which is substituted by one or more halogen atom such as fluoro, chloro, or bromo. C1-C3 haloalkoxy radical such as fluorometoxy, chloromethoxy, trifluoromethoxy, trifluoroethoxy, fluoroethoxy or fluoropropoxy is more preferred.

The term ‘arylalkyl’ refers to alkyl residue bound to aryl ring. Exemplary aryalkyl includes benzyl and phenethyl. Heteroarylalkyl refers to alkyl residues bound to heteroaryl ring. Exemplary heteroarylalkyl is pyridinylmethyl and pyridinyletyl. Alkylaryl refers to aryl residue bound to alkyl group. Exemplary alkylaryl is tolyl and mesityl.

The term ‘Heterocycle’ refers to cycloalkyl or aryl residue in which one or two carbons are substituted by hetero atom such as oxygen, nitrogen, or sulfur. Exemplary heterocycle of the present invention includes pyrrolidine, pyrazole, pyrrole, indole, quinoline, isoquinoline, tetrahydroisoquinoline, benzofuran, benzodioxan, benzodioxol (it is generally called methylenedioxyphenyl as a substitute), tetrazole, morpholine, thiazole, pyridine, pyridazine, pyrimidin, thiophene, furan, oxazole, oxazoline, isoxazole, dioxin and tetrahydrofuran.

The term ‘Haloalky’ refers to alkyl residue in which one or more H atoms are substituted by halogen atom, and comprises perhaloalkyl. Exemplary haloalkyl includes CH₂F, CHF₂ and CF₃.

The term ‘substituted’ refers to the residue comprising, not limited to alkyl, alkylaryl, aryl, arylalkyl and heteroaryl, in which H atoms not more than 3 are substituted by low alkyl, substituted alkyl, substituted alkynyl, haloalkyl, alkoxy, carbonyl, carboxyl, carboalkoxy, carboamido, acyloxy, amidino, nitro, halogen, hydroxyl, OCH(COOH)₂, cyano, primary amino, secondary amino, acylamoino, alkylthio, sulfoxide, sulfone, phenyl, benzyl, phenoxy, benzyloxy, hetroaryl, or heteroaryloxy.

In the present invention, the alkylene refers that both the ends of alkyl group are radical forms having a binding capacity, wherein the alkyl is defined as same as the above. Arylene refers that both the ends of aryl group are radical forms having a binding capacity, wherein the aryl is defined as same as the above.

Aryleneoxy means arylene-O—, wherein arylene and aryl are defined as same as the above. Aklyeneoxy means alkylene-O—, wherein alkylene is defined as same as the above.

Furthermore, any mixture of pure stereoisomers, optical antipode or diastereomers of the compounds disclosed in the present invention is included in the range of the present invention.

In one aspect of the present invention, R₄ and R₅ is preferably independently C₁-C₁₆ alkyl, cycloalkyl, alkoxyalkyl, acylalkyl, haloalkyl, or arylalkyl, more preferably, C₁-C₁₆ alkyl.

In another embodiment of the present invention, preferably, R₁, R₂ and R₃ is independently selected from the group consisting of —CO₂H, —PO₃H, —SO₃H, —CO₂, —PO₃, —SO₃, substituted or non-substituted C₁-C₂₀ alkyl, substituted or non-substituted C₆-C₃₀ aryl, substituted or non-substituted C₆-C₃₀ aryloxy, substituted or non-substituted C₆-C₃₀ arylene, substituted or non-substituted C₁-C₂₀ alkylene and substituted or non-substituted C₁-C₂₀ alkyleneoxy.

In still another embodiment of the present invention, preferably, R₁, R₂ and R₃ is independently selected from the group consisting of hydrogen, hydroxyl, —CO₂H, —PO₃H, —SO₃H, —CO₂⁻, —PO₃⁻, —SO₃⁻; R₄ and R₅ are independently C₁-C₁₆ alkyl, cycloalkyl, alkoxyalkyl, acylalkyl, haloalkyl, or arylalkyl; X or Y is CNS.

More preferably, M is Ru, R₁, R₂ and R₃ are —CO₂H (herein, n is zero), R₄ and R₅ are C₁-C₁₆ alkyl, X and Y are CNS.

The dye for dye-sensitized solar cell of the present invention can be synthesized by the following process as one embodiment:

(a) a step of obtaining a compound of Formula c by an esterification reaction of the below Formula b and an alcohol compound having a formula of R₈OH;

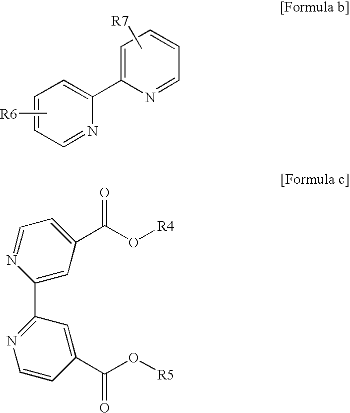

(wherein, R₆ and R₇ are independently R₉COOH, herein, R₈ and R₉ are same as the definition of R₄ and R₅ in Formula 1)
(b) a step of coordinating a covalent bond between the compound of Formula and transition metal complex; and
(c) a step of obtaining a compound of Formula 1 by reacting with a ligand precursor of the Formula a.

Hereinafter, a synthesis method of the following Formula 2, which is the representative compound among the compounds of Formula 1, is described:

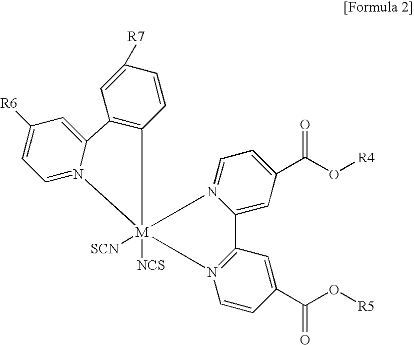

wherein, M is a transition metal, and R₄ to R₇ is defined as same as the above.

The following compound of Formula b is esterificated with alcohol compounds of Formula R₃OH to obtain a compound of Formula c, referring to the well-known esterification reaction (Sprintschnik G. et al., the American Chemical Society:4947, 1977). Herein, R₈ is same as the definition of R₄ and R₅ in Formula 1.

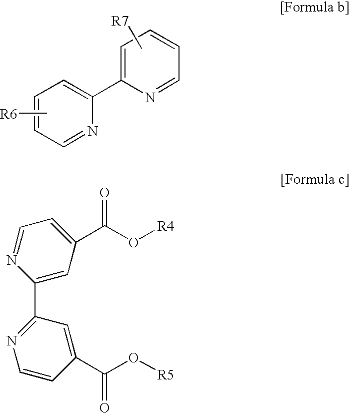

(in formula b, R₆ and R₇ are identifiably defined as the above. And in formula c, of R₄ and R₅ are identifiably defined as the above in Formula 1)

This compound of Formula c is reacted with the complex comprising a transition metal and a compound comprising NCS to obtain the compound of Formula 2 (Refer to Nazeeruddin Md. K. et al., Coordination Chemistry Reviews 248:1317, 2004).

The present invention still provides a dye-sensitized solar cell comprising the said dye.

More specifically, the dye-sensitized solar cell comprises:
a first electrode comprising a conductive transparent substrate;
a light absorbing layer formed on any one side of the first electrode, a second electrode arranged to confront the first electrode on which the light absorbing layer formed; and
an electrolyte filled between the first electrode and the second electrode,
   wherein the light absorbing layer comprises the said dye and semiconductor particles

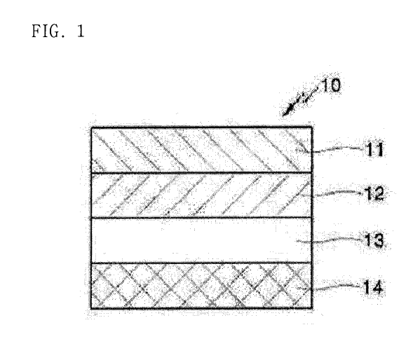

FIG. 1 is a rough diagram of the dye-sensitized solar cell according to one embodiment of the present invention. Referring to the FIG. 1, a dye-sensitized solar cell (10) has a sandwich structure which two of platelike transparent electrodes (the first electrode (11) and the second electrode (14)) are plane-connected each other. A light absorbing layer (12) is formed on the any side of the transparent electrode (11); and the said a light absorbing layer(12) comprises semiconductor particles and light-sensitized dye adhered thereto, in which electrons are exited by absorption of a visible ray. Moreover, an electrolyte (13) for oxidation-reduction is filled in the space of two electrodes.

Hereinafter, it is explained how the solar cell works.

At first, when the sunlight is introduced into dye-sensitized solar cell, a photon (light quantum) is absorbed in dye molecules of light absorbing layer (12), thereby occurring an electronic-transition from ground state to excited state. Electrons of the excited state are injected into the conduction band of interface of semiconductor particles, and the injected electrons are transported to the first electrode (11) through the interface, and then transported to the second electrode (14) through an external circuit.

Furthermore, the oxidized dye by electronic-transition is reduced by the couple ions for oxidation-reduction in electrolyte layer (13); and the oxidized ions are performed a reduction reaction with electrons reached to interface of the second electrode (14), thereby forming a charge neutrality and working the dye-sensitized solar cell.

As a conductive transparent substrate (10) of the first electrode (working electrode, semiconductor electrode), the materials having a conductivity and transparency can be used. Specifically, glass substrate or plastic substrate comprising one or more materials selected from the group consisting of indium tin oxide (ITO), fluorine tin oxide (FTO), ZnO—(Ga₂O₃ or Al₂O₃) and tin-based oxide, but are non-limited thereto. More preferably, SnO₂ having a high conductivity, transparency and thermostability or ITO having a moderate price can be used. Exemplary plastic substrate includes poly ethylene terephthalate (PET), poly ethylene naphthalate (PEN), poly carbonate (PC), polypropylene (PP), polyimide (PI) and tri acetyl cellulose (TAC), and the like.

The light absorbing layer (12) located in the conductive transparent substrate comprises semiconductor particles doped with the materials selected from the group consisting of Ti, In, Ga and Al; and the dye according to the present invention, which is adhered to the said semiconductor particles and in which electrons are exited by absorption of visible light.

As the semiconductor particles, an elemental semiconductor such as silicon, a metal oxide, or Perovskite-structured complex metal oxide can be used. Specifically, exemplary semiconductor particles include Si, TiO₂, SnO₂, ZnO, WO₃, Nb₂O₅, and TiSrO₃, etc., more preferably, Aanatase type of TiO₂. The kinds of semiconductor are not limited to the above, and can be used independently or in two or more combination thereof.

Furthermore, preferably, the surface area of semiconductor particles is larger so that the dye absorbs lots of light; more preferably, they have a mean particle diameter not more than 50 mm, most preferably, 15 to 25 mm.

The dye is as previously explained.

A light absorbing layer comprising semiconductor particles and dye may have a thickness not more than 25 μm, preferably, 1 to 25 μm. When the thickness of light absorbing layer is over 25 μm, a series resistance is increased owing to the structure, and such increase of the series resistance leads to a loss of conversion efficiency. Therefore, the thickness not more than 25 μm can retain a necessary function and keep the series resistance low to prevent from loss of conversion efficiency.

As the second electrode (counter electrode) (14), the materials can be used without limitation, if the materials have conductivity. Even if insulating materials, when a conductive layer is established on the side faced to the first electrode, they can be used. Specifically, one or more materials are selected from the group consisting of Pt, Au, Ni, Cu, Ag, In, Ru, Pd, Rh, Ir, Os, C, and conductive polymer.

Accordingly, the exemplary second electrode has a conductive layer comprising one or more materials selected from the group consisting of Pt, Au, Ni, Cu, Ag, In, Ru, Pd, Rh, Ir, Os, C, and conductive polymer, on the glass substrate or plastic substrate comprising one or more materials selected from the group consisting of indium tin oxide (ITO), fluorine tin oxide (FTO), ZnO—(Ga₂O₃ or Al₂O₃) and tin-based oxide.

The plane faced to the first electrode for improving a catalyst effect of oxidation-reduction is preferred to have a micro-structure to increase a surface area. For example, Pt or Au is preferred in black state (‘black state’ means the state of non-deposited on supports) and carbon is preferred in porous state. Especially, a platinum black state may be formed by anodizing technique or treating with chloroplatinic acid; and the porous carbon may be formed by sintering carbon particles or plasticizing organic polymers.

The electrolyte layer (13) consists of electrolyte solution. The electrolyte solution contains iodide/triodide pairs and plays a role to transport electrons from the counter electrode to dye by oxidation-reduction. A voltage of open circuit depends on the difference between energy level of dye and oxidation, reduction level. The electrolyte solution is uniformly dispersed a space between the first electrode and the second electrode, and it may be infiltrated in the light absorbing layer.

As the said electrolyte solution, exemplary solution is the solution that iodine is dissolved in acetonitrile, but is not limited thereto; any materials having a hole-conductivity can be used.

The dye-sensitized solar cell according to one embodiment of the present invention, which has the pre-described structure, can be manufactured by the following steps:
a step of manufacturing a first electrode using a conductive transparent substrate;
a step of forming a light absorbing layer comprising a dye and semiconductor particles on one side(plane) of the first electrode;
a step of manufacturing a second electrode;
a step of arranging the first electrode and the second electrode so as to face each other; and
a step of filling electrolyte solution in the space of the first electrode and second electrode and sealing it

The above method is widely known in the art and a person skilled in the art can understand well enough the contents, thus detailed explanation would be omitted herein. Just, hereinafter, the process forming dye layer, which is a main feature of the present invention is explained.

At first, a conductive transparent substrate is provided for the first electrode, and coated with paste comprising semiconductor particles on the side of the substrate and heated to prepare the particles layer as a form of porous membrane.

Herein, depending on the coating method, the different properties of the paste are required. Generally, the paste can be used in coating by Doctor Blade method or screen printing etc. To form a transparent membrane, spin coating or spray coating method can be used. Besides, general wet coating may be used. Heat-treatment is performed at 400 to 600° C. for 30 min in case of adding a binder, and it is possible to perform at not more than 200° C. in case of non-adding a binder.

To maintain a porous of membrane, polymers can be added to the porous membrane and heated at 400 to 600° C., thereby improving porosity. At this time, the polymers should be selected not to remain organic materials after heat treatment.

Appropriate polymer is ethylene cellulose (EC), hydroxyl propyl cellulose (HPC), polyethylene glycol (PEG), polyethylene oxide (PEO), polyvinyl alcohol (PVA) and polyvinyl pyrrolidone (PVP), and the like. Among them, the one having an appropriate molecular weight may be chosen and added referring to the coating conditions.

The addition of such polymer improves a dispersibility and viscosity, thereby improving a membrane property and an adhesive power the substrate. A dispersion solution comprising a dye is sprayed, coated or immersed on the prepared semiconductor particle layer so that the dye is adhered to the semiconductor particles, thereby forming a dye later.

The first electrode having the semiconductor particles is immersed in the dispersion solution comprising the dye, and after 12 hrs, the dye can be naturally adhered to the semiconductor particles. As a dye, those described previously can be used, and a solvent is not limited to acetonitrile, dichloromethane, alcohol-based solvent to disperse the dye.

Furthermore, the dispersion solution comprising a dye can comprise further an organic dye having various colors to improve absorption of a visible light of long wave, thereby improving an efficiency of the solar cell. Exemplary organic dye is cumarine and pheophorbide A (a kind of porphyrin), and so on.

After formation of the dye layer, non-adhered dye is washed by a solvent washing method to form a light absorbing layer.

A separate conductive transparent substrate is provided for Physical Vapor Depositin (PVD) method such as electroplating, sputtering and E-beam evaporation to form a conductive layer comprising conductive materials, which is ready for the second electrode.

The first electrode and the second electrode are arranged so that the prepared light absorbing layer confronts the second electrode, and then electrolyte solution is filled in the space of the light absorbing layer and second electrode and followed of sealing it to provide the dye-sensitized solar cell according to one embodiment of the present invention.

The first electrode and the second electrode can be plane-connected using an adhesive. Exemplary adhesive is thermoplastic polymer film, for example, Srlyn (Dupont company). Such thermoplastic polymer film is placed between two electrodes and heat-compressed to seal hermetically. Another kinds of the adhesive is epoxy resin or UV curing agent, at this time, it is possible to cure after heat-treatment or UV treatment.

### EXAMPLES

Hereinafter, the present invention will be described in more detail by examples and comparisons. However, it is obvious to a person skilled in the art that these examples are for illustrative purpose only and are not construed to limit the scope of the present invention.

### Example 1

### Synthesis of cis-bis(isothiocyanato)bis(2,2′-bipyridyl-4,4′-dicarboxylato)-ruthenium(II) bis(2,2′-pyridyl-4,4′-dicarboxylic acid dihexadecylester as a dye of the dye-sensitized solar cell

### (1) Synthesis of 2,2′-bipyridyl-4,4′-dicarboxylic acid dihexadecylester

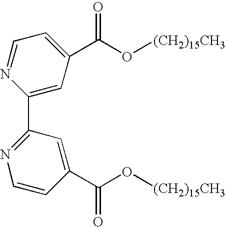

In three neck flask, 5 ml of 2,2′-bipyridyl-4,4′-carboxylic acid and thionylchloride were reacted for 3 hrs at 75˜85° C. to abstain a yellow crystal. The remained thionylchloride was evaporated under vacuum.

The yellow crystal was added with 30 ml of benzene, and further added with an excess of 1-hexanol (20.5 mmol). This mixture was reacted at 75˜85° C. for 2 hrs, and then added with 30 ml of chloroform and followed by neutralizing with 0˜4° C. of cold water-solution of sodium bicarbonate.

The lower layer was separated by a separatory funnel, and recrystallized with acetone and chloroform to abstain a colorless crystal of 2,2′-bipyridyl-4,4′-dicarboxylic acid dihexadecylester.

### (2) Synthesis cis-bis(isothiocyanato)bis(2,2′-bipyridyl-4,4′-dicarboxylato)-ruthenium(II) bis(2,2′-pyridyl-4,4′-dicarboxylic acid dihexadecylester

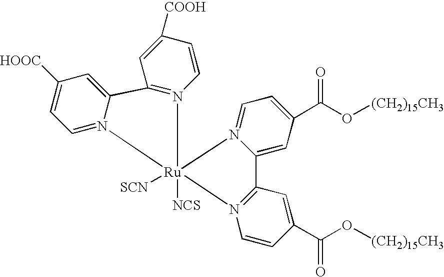

The prepared 2,2′-bipyridyl-4,4′-dicarboxylic acid dihexadecylester and [RuCl₂-(p-cymene)]₂(0.16 mmol) were dissolved in 50 ml of demethylformamide (DMF). The reacted mixture was stirred at 50˜75° C. for 4 hrs. Then, 0.32 mmol of 2,2′-bipyridyl-4,4′-dicarboxylic acid was added to the solution and reacted for 4 hrs at 150˜170° C.

An excesses of NH₄NCS (10 mmol) was added to the reactants, and further reacted for 5 hrs at 140˜150° C., then, the flask was kept cold. The remained solvent was removed by using a rotary evaporator under vacuum.

The resultant materials were washed with distilled water and diethyl ether several times, and filtered to abstain the cis-bis(isothiocyanato)bis(2,2′-bipyridyl-4,4′-dicarboxylato)-ruthenium(II) bis(2,2′-pyridyl-4,4′-dicarboxylic acid dihexadecylester. [yield: 40.8% (75 mg)]

Elemental Analysis of C₅₈H₈₀N₆O₈RuS₂

Calculated value: C60.34; H6.98; N7.28; S5.55

Measured value: C56.49; H8.79; N6.92; S8.47

### Example 2

### Synthesis of cis-bis(isothiocyanato)bis(2,2′-bipyridyl-4,4′-dicarboxylato)-ruthenium(Mbis(2,2′-pyridyl-4,4′-dicarboxylic acid dioctyl ester as a dye of the dye-sensitized solar cell

### (1) Synthesis of 2,2′-bipyridyl-4,4′-dicarboxylic acid dihexadecylester

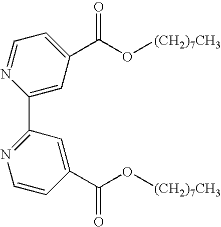

In three neck flask, 5 ml of 2,2′-bipyridyl-4,4′-carboxylic acid and thionylchloride were reflux-heated for 3 hrs at 75˜85° C. to abstain a yellow crystal. The remained thionylchloride was evaporated under vacuum.

The yellow crystal was added with 30 ml of benzene, and further added with an excess of 1-octanol (20.5 mmol), and followed by reflux-heating at 75˜85° C. for 3 hrs. 30 ml of chloroform was added thereto and followed by neutralizing with 0˜4° C. of cold water-solution of sodium bicarbonate.

The lower layer was separated by a separatory funnel and recrystallized with acetone and chloroform to abstain a colorless crystal of 2,2′-bipyridyl-4,4′-dicarboxylic acid dioctylester.

### (2) Synthesis of cis-bis(isothiocyanato)bis(2,2′-bipyridyl-4,4′-dicarboxylato)-ruthenium(II) bis(2,2′-pyridyl-4,4′-dicarboxylic acid dioctylester

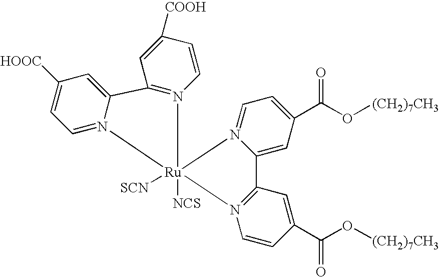

The prepared 2,2′-bipyridyl-4,4′-dicarboxylic acid dioctylester and [RuCl₂-(p-cymene)]₂(0.16 mmol) were dissolved in 50 ml of demethylformamide (DMF). The reacted mixture was stirred at 60° C. for 4 hrs. Then, 0.32 mmol of 2,2′-bipyridyl-4,4′-dicarboxylic acid was added thereto and reflux-heated for 4 hrs at 160° C.

An excesses of NH₄NCS (10 mmol) was added to the reactants, and further reacted for 5 hrs at 140˜150° C., then, the flask was kept cold. The remained solvent was removed by using a rotary evaporator under vacuum.

The resultant materials were washed with distilled water and diethyl ether several times, and filtered to abstain the cis-bis(isothiocyanato)bis(2,2′-bipyridyl-4,4′-dicarboxylato)-ruthenium(II) bis(2,2′-pyridyl-4,4′-dicarboxylic acid dioctylester. [yield: 95% (140 mg)]

IR: a strong absorption band at 3427. 2925. 2467. 2111. 1978. 1717. 1605. 1549. 1457. 1408. 1366 and 1265 cm⁻¹.

Elemental Analysis of C₄₂H₄₈N₆O₈RuS₂

Calculated value: C54.24; H5.20; N9.04; 56.90

Measured value: C47.78; H3.48; N11.58; S5.88

### Example 3

### Manufacturing of the Dye-Sensitized Solar Cell

A transparent conductor of indium-doped tin oxide is coated with a dispersion solution comprising titanium oxide particles on area of 1 cm² using the Doctor Blade method, and performed a thermoplastic process for 30 min to abstain a porous membrane of titanium oxide having a thickness of 18 μm.

And then, the specimen was kept 80° C. and immersed in 0.3 mM of dye dispersion solution for more than 12 hrs, which the prepared dye was dissolved in ethanol in order to be adhered with the dye.

The dye-adhered porous membrane of titanium oxide was washed with ethanol, and dried at ambient temperature to manufacture the first electrode formed with a light absorbing layer

For the second electrode, a transparent conductor of indium-doped tin oxide is deposited with Pt using a sputter to about 200 nm thickness, and drilled to make a micro hole by a driller of 0.75 mm diameter for injecting an electrolyte solution, thereby manufacturing the second electrode.

Thermoplastic polymer film having a 60 μm thickness was placed between the first and the second electrode and compressed at 100° C. for 9 sec to connect those two electrodes. The electrolyte solution for oxidation-reduction was injected through the micro hole formed in the second electrode, and followed by sealing the micro hole using cover glass and thermoplastic polymer film to manufacture the dye-sensitized solar cell.

Herein, the used electrolyte solution for oxidation-reduction was the solution of 0.62M of 1,2-dimethyl-3-hexylimidazolium iodide, 0.5M of 2-aminopyrimidine, 0.1M of LiI and 0.05M of I₂ dissolved in acetonitrile.

### INDUSTRIAL APPLICABILITY

The present invention relates to an amphiphile dye having a high stability in electrolyte and semiconductor particles, it can be used as a dye for dye-sensitized solar cell.

Moreover, the dye-sensitized solar cell costs low compared to preexisted silicon solar cell, and it can be applied to glass windows in outer wall of buildings or glass house because of transparent electrode.

Accordingly, the present invention can contribute to commercialization of the solar cell, thereby making sure of importance of solar energy as an energy source replaceable for oil resource.

1. A dye for dye-sensitized solar cell, which comprises a metal complex having the structures represented by the following chemical formula 1: 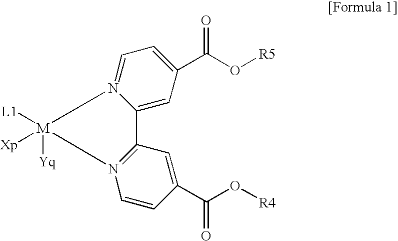
wherein,
M is a transition metal;
L1 is a ligand of the following formula (a) 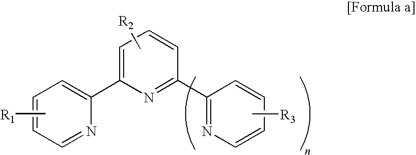
(herein, R₁, R₂, and R₃ are independently selected from —CO₂H, —PO₃H, —SO₃H, —CO₂⁻, —PO₃⁻, —SO₃⁻, alkyl, alkoxy, aryl, heteroaryl, acyl, arylene, alkylene, aryloxy, or alkyleneoxy; n is an integer of zero or one);
R₄ and R₅ are independently selected from alkyl, cycloalkyl, alkoxyalkyl, acylalkyl, haloalkyl or arylalkyl;
X and Y are independently selected from the group consisting of H, NO₂, Cl, Br, I, CN, CNS, H₂O, NH₃, Cl⁻, Br⁻, I⁻, CN⁻, CNS⁻ and PF₆;
p and q are independently an integer of zero to four.

2. The dye for dye-sensitized solar cell according to claim 1, wherein the M is selected from the group consisting of Ru, Os, Ir, Co, Rh, Zr, Zn and Pd.

3. The dye for dye-sensitized solar cell according to claim 1, wherein R₄ and R₅ are independently C₁-C₁₆ alkyl, cycloalkyl, alkoxyalkyl, acylalkyl, haloalkyl, or arylalkyl.

4. The dye for dye-sensitized solar cell according to claim 1, wherein R₄ and R₅ are C₁-C₁₆ alkyl.

5. The dye for dye-sensitized solar cell according to claim 1, wherein R₁, R₂ and R₃ is independently selected from the group consisting of —CO₂H, —PO₃H, —SO₃H, —CO₂⁻, —PO₃⁻, —SO₃⁻, substituted or non-substituted C₁-C₂₀ alkyl, substituted or non-substituted C₆-C₃₀ aryl, substituted or non-substituted C₆-C₃₀ aryloxy, substituted or non-substituted C₆-C₃₀ arylene, substituted or non-substituted C₁-C₂₀ alkylene and substituted or non-substituted C₁-C₂₀ alkyleneoxy.

6. The dye for dye-sensitized solar cell according to claim 1, wherein the alkoxy is selected from the group consisting of alkoxy having 1 to 6 carbons and haloalkoxy substituted by one or more halogen atom.

7. The dye for dye-sensitized solar cell according to claim 1, wherein the aryl has one or more substitutes selected from the group consisting of hydroxy, halo, haloalkyl, nitro, cyano, alkoxy, and low alkylamino of from 1 to 6 carbons.

8. The dye for dye-sensitized solar cell according to claim 1, wherein R₁, R₂ and R₃ is independently selected from the group consisting of hydrogen, hydroxyl, —CO₂H, —PO₃H, —SO₃H, —CO₂⁻, —PO₃⁻, and —SO₃⁻; R₄ and R₅ are independently C₁-C₁₆ alkyl, cycloalkyl, alkoxyalkyl, acylalkyl, haloalkyl, or arylalkyl; and X or Y is CNS.

9. The dye for dye-sensitized solar cell according to claim 1,
wherein M is Ru;
R₁, R₂ and R₃ are —CO₂H, herein, n is zero;
R₄ and R₅ are C₁-C₁₆ alkyl;
X and Y are CNS.

10. A dye-sensitized solar cell comprising:
a first electrode comprising a conductive transparent substrate,
a light absorbing layer formed on one side of the first electrode,
a second electrode arranged to confront the first electrode on which the light absorbing layer formed, and
an electrolyte filled between the first electrode and the second electrode;
wherein the light absorbing layer comprises semiconductor particles and the dye according to claim 1.

11. The dye-sensitized solar cell according to claim 10, wherein the conductive transparent substrate is a glass substrate or plastic substrate comprising one or more materials selected from the group consisting of indium tin oxide (ITO), fluorine tin oxide (FTO), ZnO—Ga₂O₃, ZnO— Al₂O₃ and tin-based oxide.

12. The dye-sensitized solar cell according to claim 11, wherein the plastic substrate comprises one or more materials selected from the group consisting of poly ethylene terephthalate (PET), poly ethylene naphthalate (PEN), poly carbonate (PC), polypropylene (PP), polyimide (PI) and triacetyl cellulose (TAC).

13. The dye-sensitized solar cell according to claim 10, wherein the semiconductor particles are selected from the group consisting of elemental semiconductor, metal oxide and perovskite-structured complex metal oxide.

14. The dye-sensitized solar cell according to claim 10, wherein the semiconductor particles are selected from the group consisting of TiO₂, SnO₂, ZnO, WO₃, Nb₂O₅, and TiSrO₃.

15. The dye-sensitized solar cell according to claim 10, wherein the semiconductor particles have a mean particle diameter of 15 to 50 mm.
